(19) United States
(12) Patent Application Publication
(10) Pub. No.: US 2026/0310621 A1
(43) Pub. Date: Oct. 8, 2026

(54) INTEGRATED CIRCUIT WITH ANALOG IN-MEMORY COMPUTE AND OPTICAL INTERCONNECT

(71) Applicant: OPTOML Pte Limited, Singapore (SG)

(72) Inventor: Saravana Maruthamuthu, Chennai (IN)

(21) Appl. No.: 19/637,222

(22) Filed: Apr. 2, 2026

(30) Foreign Application Priority Data
Apr. 4, 2025 (IN) 202511033415

(51) Int. Cl. G06F 13/36

(52) U.S. Cl. CPC G06F 13/36; G06F 2213/40

(57) ABSTRACT

An integrated circuit comprises a first cluster chiplet comprising a plurality of tiles laterally arranged, each of the tiles comprising at least one processor core integrated with a cache, an artificial intelligence (AI) accelerator core coupled to the at least one processor core, a digital access subsystem coupled to the AI accelerator core; and a cluster bus coupled to the digital access subsystem; a second optical chiplet comprising a plurality of optical elements and a plurality of optical interconnects coupled to the cluster bus of each of the plurality of tiles; and a silicon interposer vertically stacked with the first cluster chiplet and the second optical chiplet, wherein the silicon interposer is arranged in between the first cluster chiplet and the second optical chiplet.

### RELATED APPLICATION

The present application claims priority to Indian Patent Application No. 202511033415, filed Apr. 4, 2025, the entire contents of which are hereby incorporated by this reference.

### FIELD OF INVENTION

The invention generally relates to processors, and more particularly, to integrated circuit with analog in-memory compute and optical interconnect.

### BACKGROUND

In the field of Artificial Intelligence (AI), deep learning and neural network workloads require substantial computational resources to process large datasets and execute complex algorithms. To meet increasing performance and efficiency demands, System-on-Chip (SoC) architectures integrate multiple processing components, including Central Processing Unit (CPU) cores, Graphics Processing Unit (GPU) cores, AI accelerators, memory, and communication interfaces, within a single chip or multi-die package. AI accelerators are specialized processors optimized for high-throughput mathematical operations, such as matrix multiplications and convolutions, enabling efficient execution of large-scale AI workloads under power, area, and thermal constraints.

FIG. 1 illustrates an example of an integrated circuit 100 corresponding to the AI accelerator with current architecture as known in the art. The integrated circuit 100 includes a system-on-chip 102 comprising a plurality of clusters 104 such as cluster 104-1 through cluster 104-N (hereinafter referred to as the ‘cluster 104’). Each cluster 104 comprises a processor core 106 (referenced as 106-1 to 106-N) integrated with a cache 108 (referenced as 108-1 to 108-N) and a digital tensor compute accelerator (DTCA) core 110 (referenced as 110-1 to 110-N) communicatively coupled with a scratchpad memory (SPM) 112 (referenced as 112-1 to 112-N). Examples of the processor cores 106 include, but not limited to CPU. The integration of the cache 108 enables storing frequently accessed data near the processing core. Examples of DTCA core 110 include, but not limited to, application-specific integrated circuits (ASICs) optimized for tensor computations, tensor processing cores integrated in graphics processing units (GPUs), and other specialized hardware accelerators for matrix and tensor operations in AI workloads. Examples of the SPM 112 include, but not limited to, Digital In-Memory Computing (DIMC) memory, Static Random-Access Memory (SRAM). The DTCA core 110 is coupled with the SPM 112 enabling high-speed temporary storage of computation data. Typically, in the current architecture, the DTCA cores 110 are optimized for matrix operations prevalent in AI algorithms and the processor cores 106 are dedicated control processors for task scheduling, synchronization, and execution control.

The processor core 106 and the DTCA core 110 are communicatively coupled to each other via an interface (interchangeably referred to as ‘PC-DTCA-IF’) 114 (referenced as 114-1 to 114-N), The interface 114 enables efficient data transfer between the processor core 106 and the DTCA core 110. The processor core 106 and the DTCA core 110 are further communicatively coupled to each other with a cluster bus 116 (referenced as 116-1 to 116-N) via the cache 108 and the SPM 112. The cluster bus 116 facilitates internal communication between the processor core 106, the DTCA core 110, the cache 108 and the SPM 112 within the cluster 104.

Further, the plurality of clusters 104 are communicatively coupled with each other via a system bus 118. Examples of the system bus 118 include, but not limited to, high-speed digital buses and network-on-chip (NoC) architectures and can be selected based on optimizing various parameters such as latency, throughput, AI performance, traffic, congestion. The system bus 118 is further communicatively coupled with one or more external memory interface (EXT-MEM-IF) 120 and one or more external high-speed input-out interface (EXT-IO-IF) 122. Example of the external high-speed input-output interface includes, but not limited to, high-speed Serializer/Deserializer (SERDES). The system bus 118 can communicatively couple with one or more external memory (EXT-MEM) 124 via the external memory interface 120 to provide additional storage capacity. Example of the external memory 124 includes, but not limited to, Double Data Rate Random Access Memory (DDR-RAM). The system bus 118 can further communicatively couple with one or more external host processor 126 via the external high-speed input-out interface 122 to enable high speed data transfer between the integrated circuit 100 and the external host processor 126.

However, the current AI accelerator architectures of the integrated circuit 100 face significant challenges in achieving optimal Power-Performance-Area (PPA) efficiency. These accelerators typically exhibit power efficiencies below 2 TOPS/W, which limits scalability for growing computational demands. Increasing the number of clusters 104 to improve performance introduces space constraints and complex integrations. This reduces power efficiency and exacerbates thermal challenges.

Further, the DTCA core 110 exhibits slower computation speed when performing computations that are highly parallel or involve involve large datasets. This results in inefficiencies in compute-intensive AI and machine learning workloads. . Additionally, frequent high-speed data transfers between the DTCA core 110 and the SPM 112 introduce latency (or delays in computation), and increase power consumption, and cause traffic congestion over time, thereby reducing overall computing efficiency. In addition, the use of DIMC SPM 112 consumes substantial chip area due to the requisite additional circuitry and routing to perform in-memory operations. This poses a challenge in maintaining compact and efficient designs, particularly for large-scale memory applications demanding both high-density storage and computational capabilities.

Further, electrical interconnects are employed for chip-to-chip communication within the integrated circuit 100. However, as AI workloads scale, such interconnects constrain system performance. Electrical interconnects are subject to physical limitations that restrict achievable bandwidth at higher data rates and longer distances. Resistive, capacitive, and inductive parasitic degrade signal integrity, resulting in attenuation, distortion, timing skew, and noise. To mitigate these effects, repeaters, buffers, and equalization circuitry are introduced, which increase latency, power consumption, area utilization, and system complexity.

Further, high-speed electrical interconnects require substantial power to drive signals and preserve signal integrity in dense multi-chip or multi-package configurations such as in the integrated circuit 100. As electrical interconnects count scales to satisfy bandwidth requirements, cumulative power dissipation increases, generating localized heating and thermal hotspots. This reduces reliability and induces performance throttling. Mitigation often necessitates advanced cooling solutions, thereby reducing overall energy efficiency and scalability.

Further, large numbers of parallel electrical interconnect lanes are required as bandwidth demands increase, resulting in routing congestion in 2.5D and 3D integration architectures. Reduced trace spacing increases susceptibility to crosstalk and electromagnetic interference, necessitating shielding or increased spacing that further consumes routing resources. Moreover, limited effective communication distance restricts layout flexibility, as longer electrical interconnect lanes require additional signal conditioning and incur latency and power penalties. Collectively, these factors limit scalability of conventional electrical interconnects in high-bandwidth, low-latency AI systems.

In view of the foregoing limitations, a need exists for improved AI accelerator architectures that address bandwidth, power, thermal, and interconnect-related constraints. Existing architectures are limited in scalability due to inefficiencies in data movement and chip-to-chip communication, thereby restricting achievable performance, power efficiency, and area optimization.

### SUMMARY

The example embodiments of the present disclosure will disclose an integrated circuit with analog in-memory compute and optical interconnect. According to an aspect of the embodiments, an integrated circuit comprises a first cluster chiplet comprising a plurality of tiles laterally arranged, each of the tiles comprising at least one processor core coupled to a cache, an artificial intelligence (AI) accelerator core coupled to the at least one processor core, a digital access subsystem coupled to the AI accelerator core; and a cluster bus coupled to the digital access subsystem; a second optical chiplet comprising a plurality of optical elements and a plurality of optical interconnects coupled to the cluster bus; and a silicon interposer vertically stacked with the first cluster chiplet and the second optical chiplet, wherein the silicon interposer is arranged in between the first cluster chiplet and the second optical chiplet.

It is to be understood that the summary is not intended to identify key or essential features of embodiments of the present disclosure, nor is it intended to be used to limit the scope of the present disclosure. The object and advantages of the invention will be realized and attained by means of the elements and combinations particularly pointed out in the claims. Further, it is to be understood that both the foregoing summary and the following detailed description are exemplary and explanatory and are not restrictive of the invention.

### BRIEF DESCRIPTION OF DRAWINGS

The example embodiments will now be described with reference to the accompanying drawings, wherein:

FIG. 1 is a block diagram illustrating an example of integrated circuit as known in the art;

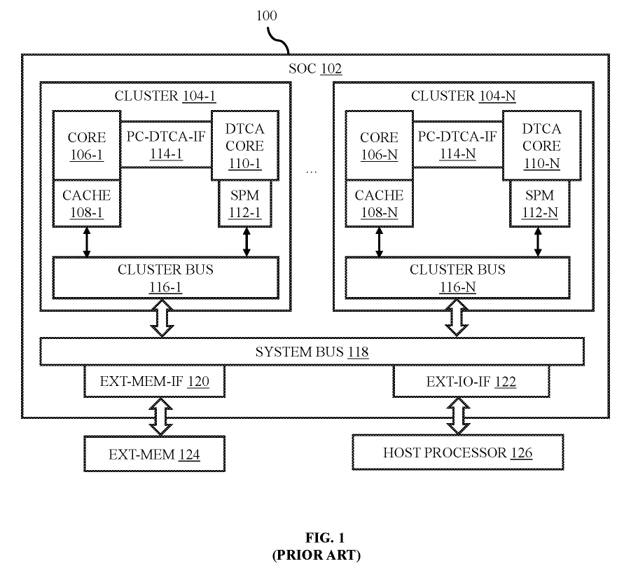

FIG. 2 is a simplified block diagram illustrating an example of integrated circuit according to various embodiments of the present disclosure;

FIG. 3 is a simplified block diagram illustrating components of the example of integrated circuit according to various embodiments of the present disclosure; and

FIG. 4 is method of operating the example of integrated circuit according to various embodiments of the present disclosure.

Throughout the drawings, the same or similar reference numerals represent the same or similar element.

### DESCRIPTION OF EMBODIMENTS

Principle of the present disclosure will now be described with reference to some example embodiments. It is to be understood that these embodiments are described only for the purpose of illustration and help those skilled in the art to understand and implement the present disclosure, without suggesting any limitation as to the scope of the disclosure. The disclosure described herein can be implemented in various manners other than the ones described below. In the following description and claims, unless defined otherwise, all technical and scientific terms used herein have the same meaning as commonly understood by one of ordinary skills in the art to which this disclosure belongs. The disclosure described herein can be implemented generally in integrated circuits and artificial intelligence (AI) systems. More particularly, the present invention relates to structure of the integrated circuit for accelerating AI based computing workloads such as AI accelerators. In addition, it is also permissible if, as the used terms and the described technical contents in the present description, terms and technical contents described in specifications and contributions as known in the AI and semiconductor industry.

Hereinafter, embodiment of the integrated circuit with analog in-memory compute and optical interconnect and disclosed in the present application will be described in detail with reference to the drawings. Note that the following embodiments do not limit the disclosed technique.

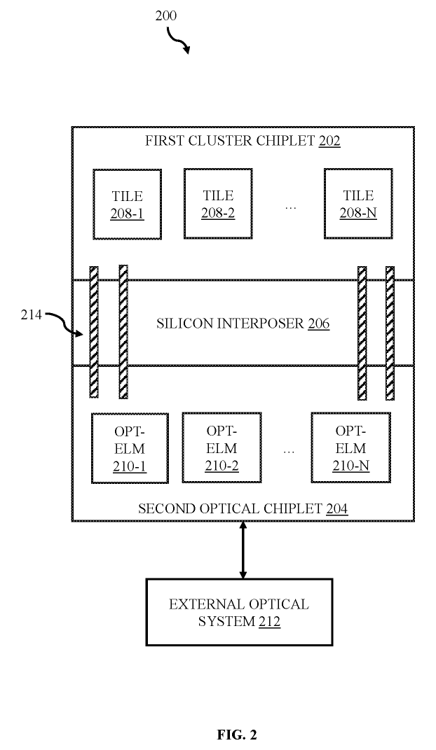

FIG. 2 is a simplified block diagram illustrating an example of integrated circuit 200 according to various embodiments of the present disclosure. Examples of the integrated circuit 200 include an artificial intelligence (AI) accelerator for accelerating AI based computing workloads. The integrated circuit 200 can be packaged in form of a system-on-chip (SOC). The integrated circuit 200 can be used for various applications within ultra-low-power edge devices and high-performance autonomous systems. Examples of application with such edge devices include, but are not limited to, smart home and consumer electronics, predictive maintenance in industrial Internet-of-Things (IoT), environmental and agriculture monitoring, and on-device AI copilots. Examples of applications within such autonomous systems include, but are not limited to, Autonomous mobile robots (AMRs), ADAS and in-cabin AI for vehicles, multi-sensor industrial automation, drones and smart surveillance systems, and edge LLM deployment in embedded platforms. The integrated circuit 200 may be initially trained offline (e.g., at the time of manufacture) and operational parameters such as clock rate, frequency, etc., may be set based on controlled inputs or learning data sets corresponding to the different workloads expected to be faced for the desired application.

The integrated circuit 200 comprises a first cluster chiplet 202, a second optical chiplet 204, and a silicon interposer 206 vertically stacked to form a three-dimensional (3D) arrangement or package. As used herein, the first cluster chiplet 202, the second optical chiplet 204, and the silicon interposer 206 are vertically stacked when the first cluster chiplet 202, the second optical chiplet 204, and the silicon interposer 206 are placed on top of each other in a column. The first cluster chiplet 202 comprises a plurality of tiles 208-1, 208-2, ... 208-N (hereinafter referred to as ‘tile 208’ in singular and ‘tiles 208’ in plural) laterally arranged. Each of the tiles 208 include at least one processor core (not shown in the figure), an AI accelerator core (not shown in the figure), and a digital access subsystem (DAS) (not shown in the figure) to perform various operations or AI workloads. Each of the tiles 208 can work independently on different operations or tasks or collaborate with each other in parallel to optimize processing efficiency for complex AI workloads. This configuration allows the integrated circuit 200 to handle a wide range of applications, from general computing tasks to more specialized operations, where parallel processing and high throughput are essential.

The second optical chiplet 204 comprises a plurality of optical elements (OPT-ELM) 210-1, 210-2, ... 210-N (hereinafter referred to as ‘optical element 210’ in singular and ‘optical elements 210’ in plural) and a plurality of optical interconnects (not shown in the figure) forming an optical network architecture within the second optical chiplet 204. The optical elements 210 and the plurality of optical interconnects enable high-speed and low-latency data communication between the first cluster chiplet 202 and an external optical system 212 coupled to the second optical chiplet 204. The plurality of optical interconnects augment or replace conventional electrical interconnects, thereby overcoming bandwidth and thermal limitations typically associated with digital-only data transmission mechanisms. The optical elements 210 include photonic switching elements such as optical transceivers, optical converters, and optical network routers.

The silicon interposer 206 is arranged in between the first cluster chiplet 202 and the second optical chiplet 204. The first cluster chiplet 202 and the second optical chiplet 204 are physically stacked and electrically coupled via the silicon interposer 206. The silicon interposer 206 serves as a substrate that facilitates high-speed lateral signal routing and power distribution across the first cluster chiplet 202 and the second optical chiplet 204. Vertical electrical communication between the first cluster chiplet 202 and the second optical chiplet 204 is enabled through a plurality of through-silicon vias (TSVs) 214, which penetrate the silicon interposer 206 to establish low-latency, high-bandwidth inter-die connections.

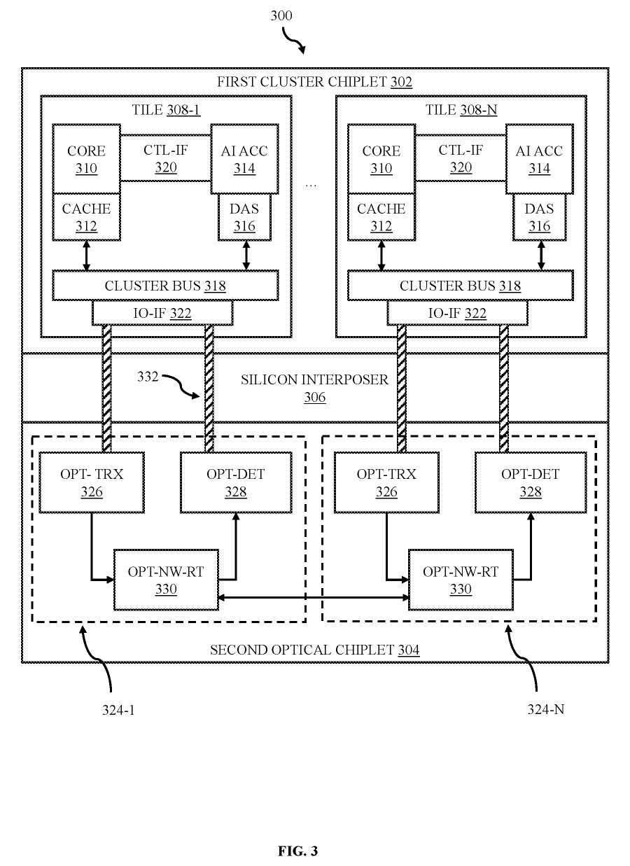

FIG. 3 is a simplified block diagram illustrating components of an example of integrated circuit 300 according to various embodiments of the present disclosure. The integrated circuit 300 comprises a first cluster chiplet 302, a second optical chiplet 304, and a silicon interposer 306 vertically stacked forming the 3D arrangement. The first cluster chiplet 302, the second optical chiplet 304, and the silicon interposer 306 are same as that of the corresponding components in the integrated circuit 200 of FIG. 2. The first cluster chiplet 302 comprises a plurality of tiles 308-1… 308-N (hereinafter referred to as ‘tile 308’ in singular and ‘tiles 308’ in plural) laterally arranged. The plurality of tiles 308 are laterally arranged within the first cluster chiplet 302 and are vertically stacked with the second optical chiplet 304 and the silicon interposer 306. Each of the tiles 308 comprises at least one processor core (PC) 310 (hereinafter referred to as ‘processor core’ in singular for brevity) coupled to a cache 312, an AI accelerator core (AI ACC) 314, a digital access subsystem (DAS) 316 coupled to the AI accelerator core 314, and a cluster bus 318. The AI accelerator core 314 is coupled to the processor core 310 through a control interface (CTL-IF) 320. The cluster bus 318 is coupled to cache 312 and the DAS 316.

In accordance with the embodiments of the present invention, the processor core 310 can be a general-purpose processor or a specialized processor based on the application of the integrated circuit 300. As such, the processor core 310 is capable of working with different types of AI models such as vision, LLMs, and generative models. Examples of the processor cores 310 include, but not limited to, NPU, RISC-V CPU, and VECT GPU. In one embodiment and as shown in the figure, each of the tiles 308 can include one processor core. In one embodiment, each of the tiles 308 can include plurality of processor cores based on the application of the integrated circuit 300. In one example of such embodiment, the processor core within each tile 308 can process data independently of each other. In one example of such embodiment, the processor core within each tile 308 can process data simultaneously in parallel to optimize processing efficiency and high throughput for complex applications.

In accordance with the embodiments of the present invention, the processor core 310 is coupled to the cache 312 within each tile 308. The cache 312 can be a small, high-speed memory for storing frequently accessed data and instructions and can be located in close proximity to the processor core 310. The location of the cache 312 within the tile 308 enables the processor core 310 to retrieve data from the cache 312 at a higher speed when compared to a slower main memory. This leads to reduced latency and optimized power efficiency as the need for power-intensive memory accesses are reduced.

In accordance with the embodiments of the present invention, the AI accelerator core 314 is a bitwise analog compute system embedded in a memory unit configured to perform a plurality of bit-wise operations in parallel upon receiving a plurality of bits simultaneously from the external digital system. The bitwise analog compute system represents the plurality of bits provided by the external digital system with one of a selected voltage level of an analog signal and a selected current level of the analog signal that are converted to digital signals for processing by the processor core 310.

To this end, the AI accelerator core 314 comprises an array of memory cells (not shown in the figure) configured to store analog weights and execute multiply-accumulate (MAC) operations directly within the analog domain. Each memory cell serves both as a storage element and a computational node, thereby enabling in-memory analog computation. Examples of memory technologies for implementing such functionality include non-volatile memory elements such as Resistive Random-Access Memory (ReRAM), Magneto-resistive RAM (MRAM), or other emerging memory devices capable of supporting analog state storage. These memory cells may be organized into crossbar array structures. This configuration enables massively parallel MAC operations with high energy efficiency and reduced data movement, contributing to the overall performance advantages of the analog compute-in-memory architecture.

The AI accelerator core 314 performs computational tasks using analog circuitry rather than conventional digital logic and is embedded within a memory unit. In such a configuration, the memory unit serves a dual function—operating both as a data storage medium and as a computational substrate—thereby facilitating in-memory computation. Performing computations directly within memory arrays in the analog domain has been demonstrated to yield orders-of-magnitude improvements in both energy efficiency and computational throughput, particularly for operations such as dot-product and matrix multiplication. Unlike traditional digital architectures that necessitate frequent and energy-intensive data transfers between separate memory and processing units, analog in-memory computation enables the co-location of data and computational logic within the same physical array. This architectural co-integration significantly reduces the overhead associated with data movement, leading to a substantial gain in system efficiency, with reported improvements of up to 100× over conventional digital AI accelerators.

The AI accelerator core 314 with analog in-memory compute architecture within each tile 308 is faster than DIMC when processing tasks that are highly parallel or involve large datasets. This leads to higher and efficient data processing, reduced latency, and reduced power consumption as data is not transferred across multiple and distinct memory units and processors. Additionally, the AI accelerator core 314 with analog in-memory compute architecture within each tile 308 leads to optimized area usage within each tile 308. In an example, the area occupied by the AI accelerator core 314 within each tile 308 is 1.3-1.4 times compared to SRAM memory cell within each tile 308. In an example, the AI accelerator core 314 can be designed to handle specific tasks such as matrix multiplications, vector operations, and neural network inference that can directly interface with the memory unit. The AI accelerator core 314 with analog computation and in-memory architecture thus enables the integrated circuit 300 be used for applications within ultra-low-power edge devices and high-performance autonomous systems.

In one embodiment of the present invention, the AI accelerator core 314 can be communicatively coupled with an external digital system (not shown in the figure) or an external data sources (not shown in the figure) through the DAS 316. Examples of the DAS 316 include, but are not limited to, digital interfaces, digital converters, and digital controller that enable conversion of data from analog to digital and digital to analog and transfer of data between the AI accelerator core 314 (i.e., an analog computing unit) and the external data source or digital subsystem (i.e., a digital computing unit). The DAS 316 facilitates the interaction between the AI accelerator core 314 processing analog data and the external digital system or data sources processing digital data. This results in seamless communication between the AI accelerator core 314 and the external data source or digital subsystem, leading to efficient data flow and control across both analogue and digital domains. Additionally, the coupling of the AI accelerator core 314 to the DAS 316 enables enhanced hybrid computing capabilities, wherein the AI accelerator core 314 can leverage low-power, high-efficiency computation for specific tasks, while the DAS 316 ensures the results are correctly interpreted, stored, and further processed based on the application of the integrated circuit 300.

In accordance with the embodiments of the present invention, the control interface 320 facilitates exchange of data and control signals between the processor core 310 and the AI accelerator core 314. Examples of the control interface 320 include, but are not limited to, high-bandwidth data buses, control lines, and synchronization mechanisms. The control interface 320 may be configurable to adjust or control communication between the processor core 310 and the AI accelerator core 314 based on the application of the integrated circuit 300 and optimizing one or more control parameters. The one or more control parameters include workload, performance, latency, resource utilization, and power consumption. In an example, the processor core 310 is configured to perform general purpose task and the AI accelerator core 314 is optimized to perform specialized task for AI based application. The control interface 320 in such example controls the flow of data and control signals between the processor core 310 and the AI accelerator core 314.

In accordance with the embodiments of the present invention, the cluster bus 318 supports high-speed, low-latency data transmission among the various components within each of tiles 308. The cluster bus 318 can be multidirectional and can include multiple data lines to handle parallel communication, enabling the simultaneous transfer of multiple data streams for greater throughput. The cluster bus 318 can be configured to optimize energy efficiency and performance within each of the tiles 308 and within the first cluster chiplet 302.

In accordance with the embodiments of the present invention, the cluster bus 318 is coupled to an input-output interface (IO-IF) 322 to facilitate high-speed data transfer between the first cluster chiplet 302 and the second optical chiplet 304. Example of the input-output interface 322 include but not limited to serializer/deserializer. The input-output interface 322 converts parallel data streams from internal data paths into serial data for efficient transmission over high-bandwidth interconnects and subsequently converts serial data back into parallel format for internal processing. This enables seamless communication across the first cluster chiplet 302 and the second optical chiplet 304 while minimizing pin count and improving signal integrity. The inclusion of the input-output interface 322 enhances overall system performance by supporting data rates compatible with the optical network-on-chip or other high-speed communication protocols implemented in the integrated circuit 300.

In accordance with various embodiments of the present invention, the second optical chiplet 304 includes a plurality of optical elements 324-1 … 324-N (hereinafter referred to as “optical element 324” in singular and “optical elements 324” in plural) and plurality of optical interconnects (shown as bidirectional arrows). Example of the plurality of optical interconnects include optical waveguides. The plurality of optical interconnects may be fabricated within a silicon photonics layer of the second optical chiplet 304. The plurality of optical interconnects is configured to guide optical signals with high fidelity and minimal signal degradation. This significantly reduces resistive losses, capacitive coupling, and electromagnetic interference compared to traditional metal-based interconnects as the data is transported in form of light. The plurality of optical interconnects enables ultra-high-bandwidth communication channels with substantially improved signal integrity and lower power consumption per bit transferred.

In accordance with the embodiments of the present invention, the optical elements 324 are implemented in the second optical chiplet 304 to handle routing, switching, and multiplexing of data packets among the various components of the integrated circuit 300. As such, the optical elements 324 include a plurality of optical transceivers (OPT-TRX) 326 (hereinafter referred to as ‘optical transceiver 326’ in singular and ‘optical transceivers 326’ in plural), a plurality of optical detectors (OPT-DET) 328 (hereinafter referred to as ‘optical detector 328’ in singular and ‘optical detectors 328’ in plural), and a plurality of optical network routers (OPT-NW-RT) 330 (hereinafter referred to as ‘optical network router 330’ in singular and ‘optical network routers 330’ in plural),. The optical elements 324 are implemented using photonic switching elements. In some embodiments, the optical elements 324 leverage wavelength-division multiplexing (WDM) to enable simultaneous multi-channel data transfer across a single optical path, thereby enhancing data throughput and overall system scalability.

Further, the optical transceivers 326 facilitate seamless inter-chiplet communication, particularly with the analog compute elements residing on the first cluster chiplet 302. Accordingly, each of the optical transceiver 326 includes an optical conversion interface (not shown in the figure), an optical converter (not shown in the figure), an optical modulator (not shown in the figure), and an optical source (not shown in the figure) embedded within the second optical chiplet 304. The optical conversion interface is deployed at the interface boundary between the first cluster chiplet 302 and the second optical chiplet 304. The optical conversion interface converts outgoing electrical signals into optical signals for transmission through the second optical chiplet 304 and, conversely, converts received optical signals back into electrical signals for processing within the analog computing domain of the first cluster chiplet 302. Thus, the optical conversion interface enables low-latency, energy-efficient signalling between heterogeneous compute domains, with minimal protocol overhead and negligible data loss. By offloading high-volume data transport to the optical network of the second optical chiplet 304, the integrated circuit 300 achieves a marked reduction in power consumption and thermal dissipation, thereby enhancing overall performance and enabling more effective scalability compared to conventional, electrically-bound accelerator architectures.

Further, the optical converter such as serializer/deserializer (SerDes) enables bi-directional electrical-to-optical and optical-to-electrical data conversion. The optical modulator is coupled to the optical source such as on-chip laser. The optical modulator is configured to receive high-speed serialized electrical data signals from the optical converter and modulate these signals onto an optical carrier generated by the optical source. The modulated optical signal is then injected into the optical interconnect for transmission through the optical network.

Further the optical detector 328 is configured to capture incoming optical signals transmitted through the optical network. Examples of the optical detector include photodiode array and other suitable photonic sensing element that are integrated with digitizer module. The captured optical signals are converted into corresponding electrical signals, which are subsequently digitized using the integrated digitizer module. The digitized data is then relayed to the optical converter for deserialization and further routing to the appropriate processing or memory components.

Further, the optical network router 330 is configured to manage the routing of optical signals across the optical network. The optical network router 330 may employ passive or active switching elements to dynamically route optical data packets to desired destinations. The optical network router 330 further supports routing protocols and control logic to handle dynamic bandwidth allocation, path arbitration, and congestion avoidance, thereby ensuring efficient and low-latency communication among chiplets and system subsystems.

Thus, the integrated arrangement of the optical elements 324 comprising of the optical transceivers 326, which itself comprises the optical conversion interfaces, the optical converters, the optical modulators, and the optical source, the optical detectors 328, and the optical network routers 330 within the second optical chiplet 304 enables robust, scalable, and energy-efficient communication across the multi-chiplet system, providing a foundational interconnect framework for advanced high-performance computing platforms.

In accordance with the various embodiments of the present invention, the silicon interposer 306 includes a plurality of metallization layers (not shown in the figure) in which one end of the optical interconnects are embedded. The optical interconnects are employed to physically and electrically connect first cluster chiplet 302 and second optical chiplet 304 within the 3D arrangement. The metallization layers provide high-density electrical routing channels for power delivery, control signals, and low-speed data paths, while the embedded optical interconnects, such as waveguides, enable high-speed optical communication between the first cluster chiplet 302 and the second optical chiplet 304. The integration of both electrical interconnects and the optical interconnects within the silicon interposer 306 allows for heterogeneous data transport optimized for bandwidth, latency, and energy efficiency. The optical interconnects may further include passive optical elements such as splitters, couplers, and mirroring resonators to facilitate wavelength multiplexing and routing. This co-integrated structure of the silicon interposer 306 reduces inter-chip communication delays, improves signal integrity, and enables scalable chiplet interconnection for high-performance AI processing.

Further, through-silicon vias (TSVs) 332 are employed to establish vertical electrical connections between stacked layers within the 3D arrangement. These TSVs 332 facilitate the transfer of both signals and power across the first cluster chiplet 302 and the second optical chiplet 304, enabling tight integration between functional layers such as compute, memory, and interconnect subsystems. By providing short, direct inter-layer pathways, the TSVs 332 significantly reduce parasitic resistance, capacitance, and inductance compared to traditional wirebond or edge-interconnect approaches. This reduction in parasitic elements supports high-speed signal transmission and minimizes latency, thereby meeting the stringent bandwidth and timing requirements associated with AI workloads. Additionally, use of the TSVs 332 enables fine-grained power delivery to localized compute regions, improving overall power integrity and energy efficiency. Therefore, the TSVs 332 play a critical role in enabling compact, high-performance communication between first cluster chiplet and second optical chiplet, as well as facilitating data exchange with memory layers or additional compute stacks when implemented in a vertically scaled AI accelerator architecture.

In accordance with the various embodiments of the present invention, the integrated circuit 300 incorporates thermal management strategies integral to the 3D arrangement as the analog compute arrays within each of the tiles 308, i.e., the processor core 310 and the AI accelerator core 314 are typically configured to operate at moderate voltage levels suitable for efficient matrix operation that may generate substantial heat, during large-scale or high-density matrix computations. Accordingly, the thermal management strategies comprise dedicated thermal dissipation components (not shown in the figure), including but not limited to heat spreaders strategically embedded within or adjacent to the first cluster chiplet 302. These thermal dissipation components are constructed from thermally conductive materials and are configured to distribute and dissipate heat away from the active compute regions. The integration of such thermal management features within the 3D arrangement ensures sustained performance levels, prevents thermal bottlenecks, and extends the operational longevity of the analog compute arrays during intensive computational workloads.

Thus, the integrated circuit 300 leverages analog in-memory computation to reduce overall energy consumption by minimizing the need for frequent and high-volume data transfers between separate memory and processing units. By performing computation directly within memory arrays, the integrated circuit 300 significantly lowers power requirements, particularly for data-intensive AI workloads. In addition, the use of optical interconnects between chiplets enables high-bandwidth, low-latency data transmission, effectively mitigating the communication bottlenecks commonly associated with conventional electrical interconnects.

Further, the integrated circuit 300 employs the chiplet-based 3D arrangement strategy as described above that allows scalable deployment of multiple first cluster chiplets, each comprising analog acceleration capabilities. One or more first cluster chiplet can be interconnected via one or more second optical chiplets, providing modular expansion of both compute capacity and bandwidth. Through vertical stacking enabled by the TSVs, the integrated circuit 300 achieves high performance density, allowing for greater compute functionality per unit area compared to traditional planar designs. This 3D arrangement facilitates efficient inter-chiplet communication and supports fine-grained scaling tailored to workload demands.

Further, the vertical stacking of the first cluster chiplet 302 and the second optical chiplet 304 creates a highly compact and dense architecture, which allows for more efficient use of physical space, thereby enabling the integrated circuit 300 to achieve high computational throughput while maintaining a smaller form factor. The vertical stacking of the first cluster chiplet 302 and the second optical chiplet 304 in the integrated circuit 300 not only contributes to efficient space utilization and performance enhancement but also facilitates scalability of the system. By arranging the first cluster chiplet 302 and the second optical chiplet 304 in a layered, vertically stacked configuration, the integrated circuit 300 is able to scale effectively in terms of both computational power and memory capacity without significantly increasing the physical footprint of the integrated circuit 300.

Moreover, vertical stacking supports thermal management as the arrangement allows for better heat dissipation across the stacked layers. As the integrated circuit 300 scales to incorporate more chiplets, the ability to manage and distribute heat efficiently becomes increasingly important, and the vertical arrangement allows for more effective thermal solutions, contributing to the system's overall stability and performance.

The vertical stacking arrangement described herein can also be extended to incorporate Dynamic Random-Access Memory (DRAM) or other external memory modules into the integrated circuit 300. This extension is achieved by utilizing Through-Silicon Vias (TSVs), which enable the direct vertical integration of additional memory components, such as DRAM, with the existing chiplets.

By extending the vertical stacking arrangement to include DRAM or other external memory, the integrated circuit 300 can scale its memory capacity in a highly efficient manner, providing the necessary storage resources for high-performance workloads. The integration of external memory via TSVs further enhances the system's memory bandwidth, enabling faster data access for memory-intensive applications. The use of TSVs to integrate DRAM or external memory into the stacked configuration also allows for a more compact system design, as the memory modules can be vertically integrated with the chiplets, reducing the system's physical footprint compared to traditional memory architectures that require separate memory chips or modules placed horizontally on the board. Moreover, this integration enables the system to manage memory resources more effectively, as the stacked memory and chiplets can share thermal and power management solutions, ensuring efficient heat dissipation and optimal power distribution. The vertically integrated memory also ensures better synchronization between the chiplets and memory, improving the overall performance of the system.

In one embodiment, the plurality of optical interconnects on the second optical chiplet 304 may comprise an optical fibre termination (not shown in the figure) configured to facilitate high-bandwidth chip-to-chip communication outside the3D arrangement. The optical fibre termination may be operatively coupled to an optical transceiver (not shown in the figure) or photonic interface (not shown in the figure) integrated within each respective chip, thereby enabling the transmission and reception of optical signals across chip boundaries. Such an inter-chip optical connection offers significantly enhanced data throughput compared to traditional electrical interconnects, while also reducing signal degradation, electromagnetic interference, and power consumption typically associated with high-speed electrical interfaces.

In another embodiment, the optical fibre termination may include a connector assembly (not shown in the figure) designed to align and secure the optical fibres to the photonic interfaces on the chips. The connector assembly may incorporate precision alignment features to ensure optimal coupling efficiency between the optical fibres and the photonic interfaces. Additionally, the optical transceivers integrated within the chips may comprise laser diodes for transmitting optical signals and photodetectors for receiving optical signals, thereby facilitating bidirectional optical communication.

In another embodiment, the optical interconnects may be configured to support various communication protocols, for example, ethernet to enable seamless integration with existing data communication infrastructure. The optical interconnects may also include wavelength-division multiplexing (WDM) capabilities to further enhance data throughput by allowing multiple optical signals at different wavelengths to be transmitted simultaneously over a single optical fibre.

Therefore, the present invention offers several technical advantages over conventional AI accelerator architectures. First, the integration of analog in-memory computation within first cluster chiplet significantly reduces energy consumption by minimizing the need for frequent and large-volume data transfers between memory and compute cores. By performing core AI operations, such as matrix multiplications, directly within memory arrays, the invention effectively eliminates one of the most energy-intensive aspects of traditional AI processing—data movement—thereby enhancing overall energy efficiency.

Second, the incorporation of optical interconnect technology within second optical chiplet and between second optical chiplet and chips and/or communication infrastructure located externally to the 3D package enables ultra-high bandwidth and low-latency data communication between chiplets and across system subsystems. Optical signaling over embedded waveguides mitigates the bandwidth bottlenecks and signal degradation commonly associated with electrical interconnects, allowing for high-throughput, scalable communication that supports the demands of modern AI workloads.

Third, the use of a chiplet-based architecture integrated within a three-dimensional (3D) package provides a scalable platform for heterogeneous system integration. Multiple instances of first cluster chiplet, each containing dedicated analog compute cores, can be interconnected with one or more optical communication chiplets (second optical chiplet), allowing for fine-grained scaling of both computational and communication resources. This modular approach supports flexible system design and efficient workload distribution across chiplets.

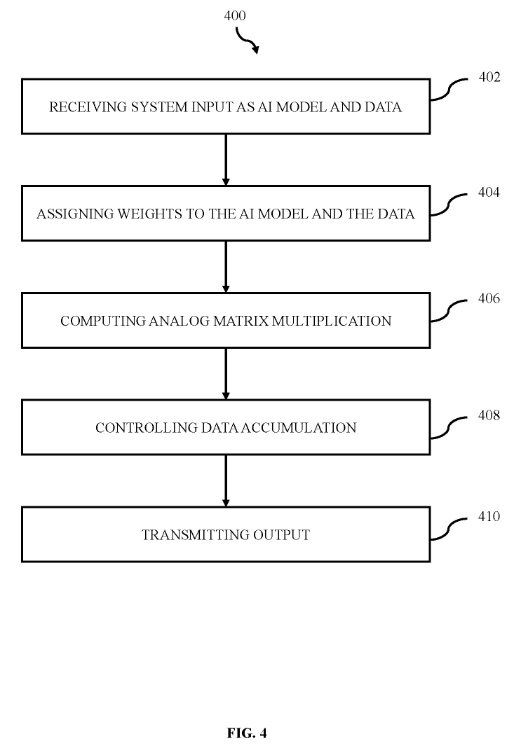

FIG. 4 is method 400 of operating the example of integrated circuit according to various embodiments of the present disclosure. The method 400 includes a series of coordinated steps that leverage analog in-memory computation, optical interconnects, and localized control processing to achieve high-throughput, energy-efficient AI inference and training. The method 400 can be implemented by the components of the integrated circuit 300.

At step 402, the method 400 includes receiving AI model and data as system input in the integrated circuit 300.

At step 404, i.e., at initiation stage, the method 400 includes associating weights with the AI model and the data and storing the associated weights in the cache 312 of the first cluster chiplet 302. In some examples, the weights may be stored using non-volatile memory technologies such as ReRAM, MRAM, or other analog-capable memory devices. The weight corresponds to digital-to-analog conversion and control of write voltages to ensure accurate representation of parameters of the AI model.

At step 406, i.e., at compute phase, the method 400 includes computing analog matrix-multiply operations within the analog domain using the in-memory compute arrays of the AI accelerator core 314. As such, inputs to neural network layers of the AI model are applied as analog voltages, and the resulting currents through the crossbar arrays represent the computed dot-products. This compute-in-memory architecture substantially minimizes data movement between memory and processing units. During computation, intermediate results and control signals are communicated across chiplets using optical routing mechanisms. The optical network of the second optical chiplet 304 including the optical elements 324 and the optical interconnects enable the rapid transmission of data with reduced latency and electrical loading.

At step 408, i.e., at control and accumulation phase, the method 400 comprises managing the scheduling of operations, data flow, and accumulation of partial results by the processor core 310. This control logic enables autonomous execution of complex AI tasks without the need for constant supervision by an external processor. Accumulated results may be stored locally or passed onward for further stages of computation, depending on the workload and system configuration.

At step 410, the method 400 includes transmission of optical signals between one or more external components located outside the integrated circuit 300 and/or external communication network via an optical fibre. The optical interconnects on second optical chiplet 304 are provided with an optical fibre termination aligned with the photonic interface of each chip to enable low-loss optical signal transmission.

The present disclosure has been described in terms of specific embodiments, but it is to be understood that the scope of the disclosure is not limited to the particular systems or methods described. It should be recognized that those skilled in the art may make modifications and improvements without departing from the broader inventive concepts disclosed herein. Such modifications and improvements are intended to be included within the scope of the disclosure.

It is also to be understood that the terminology used herein is for the purpose of describing particular embodiments only and is not intended to be limiting. The scope of the disclosure is defined by the claims, and all equivalents thereof, as would be understood by those skilled in the art.

We claim:

1. An integrated circuit comprising:
a first cluster chiplet comprising:
a plurality of tiles laterally arranged, each of the tiles comprising:
at least one processor core coupled to a cache,
an artificial intelligence (AI) accelerator core coupled to the processor core,
a digital access subsystem coupled to the AI accelerator core; and
a cluster bus coupled to the digital access subsystem;
a second optical chiplet comprising a plurality of optical elements and a plurality of optical interconnects coupled to the cluster bus of each of the plurality of tiles; and
a silicon interposer vertically stacked with the first cluster chiplet and the second optical chiplet, wherein the silicon interposer is arranged in between the first cluster chiplet and the second optical chiplet.

2. The integrated circuit as claimed in claim 1, wherein the digital access subsystem is configured to enable bidirectional communication between the AI accelerator core and an external digital system.

3. The integrated circuit as claimed in claim 2, wherein the AI accelerator core is a bitwise analog compute system configured to perform a plurality of bit-wise operations in parallel, wherein a plurality of bits from the external digital system are provided simultaneously and represented with one of a selected voltage level of an analog signal and a selected current level of the analog signal.

4. The integrated circuit as claimed in claim 1, wherein the at least one processor core is communicatively coupled with the AI accelerator core via a control interface and wherein the control interface is configurable to control communications based on one or more control parameters.

5. The integrated circuit as claimed in claim 4, wherein the one or more control parameters include workload, performance, latency, resource utilization, and power consumption.

6. The integrated circuit as claimed in claim 1, wherein the silicon interposer is coupled to the cluster bus of each of the plurality of the tiles in the first cluster chiplet.

7. The integrated circuit as claimed in claim 1, wherein the first cluster chiplet, the second optical chiplet, and the silicon interposer are interconnected using a plurality of through-silicon vias.
